(19) United States
(12) Patent Application Publication
(10) Pub. No.: US 2026/0287957 A1
(43) Pub. Date: Sep. 24, 2026

(54) ALIGNMENT DEVICE AND METHOD OF USING THE SAME

(71) Applicant: SILICONWARE PRECISION INDUSTRIES CO., LTD., Taichung City (TW)

(72) Inventors: Yu-Xuan SHEN, Taichung City (TW); Ting-Hsuan CHEN, Taichung City (TW); Pei-Chi HUANG, Taichung City (TW)

(73) Assignee: SILICONWARE PRECISION INDUSTRIES CO., LTD., Taichung City (TW)

(21) Appl. No.: 19/371,476

(22) Filed: Oct. 28, 2025

(30) Foreign Application Priority Data
Mar. 21, 2025 (TW) 114110789

(51) Int. Cl. G02F 1/137; G02F 1/133; H01L 21/66; H01L 21/68; H01L 21/78

(52) U.S. Cl. CPC G02F 1/137; G02F 1/13306; H10P 54/00; H10P 72/53; H10P 74/23

(57) ABSTRACT

An alignment device and a method using the same for aligning multiple components to a wafer including multiple dies are provided. The alignment device includes a laser source, a beam expander, and a liquid crystal panel having multiple liquid crystal switch units. Each die corresponds to at least one liquid crystal switch unit. By activating the liquid crystal switch unit, a beam directed toward a predetermined disposing position on the die is allowed to pass through, enabling precise alignment of a component at the predetermined disposing position. The beam expander is used to enlarge the beam emitted by the laser source, and the liquid crystal switch units are used to control the beams, directing the beams to multiple predetermined disposing positions on the wafer. Therefore, simultaneous alignment and placement of the components can be achieved, thereby significantly enhancing the efficiency of the alignment device and effectively increasing production capacity.

### BACKGROUND

### 1. Technical Field

The present disclosure relates to an alignment device, and more particularly, to an alignment device used to simultaneously align multiple components to a wafer including a plurality of dies.

### 2. Description of Related Art

With the vigorous development of portable electronic products in recent years, the development of various related products has also been moving towards high density, high performance, and a trend of being lighter, thinner, shorter, and smaller. At the same time, semiconductor devices are also gradually developing towards heterogeneous integration. As a result, three-dimensional (3D) multi-chip packaging technology has been emerging. To enhance the signal transmission speed between the increasing number of chips and various components within semiconductor devices, as well as between semiconductor devices and external circuits or components, optical communication technology has been introduced, using optical fibers as the signal transmission medium for key signal paths. Among the related technologies, Co-Packaged Optics (CPO) technology has become a key technology that the industry has vigorously developed in recent years.

In existing manufacturing technology, when connecting an optical fiber connector to a semiconductor component such as an optical engine (OE) die or a chip, the process is typically performed manually. Operators first manually direct a laser beam to the predetermined installation position of the optical fiber connector on a single die. Then, the optical fiber connector is aligned and fixed to the predetermined installation position illuminated by the laser beam using adhesive dispensing or other methods.

However, since this alignment method can only align a single installation position on a single die or chip at a time, the efficiency of both the alignment device and the alignment operation is extremely low, severely restricting the production capacity of the entire manufacturing line.

Therefore, how to overcome the above-mentioned problems of the prior art has become an urgent issue to be solved.

### SUMMARY

In view of the above-mentioned shortcomings of the prior art, the present disclosure provides an alignment device for aligning a plurality of components to a wafer including a plurality of unsingulated dies, the alignment device comprising: a laser source configured to emit a beam; a beam expander disposed between the laser source and the wafer, the beam expander configured to receive the beam emitted by the laser source, expand a range of the beam, and direct the beam toward the wafer; and a liquid crystal panel disposed between the beam expander and the wafer and having a plurality of liquid crystal switch units, wherein each of the plurality of dies corresponds to at least one of the plurality of liquid crystal switch units, wherein activation of the liquid crystal switch unit allows the beam directed toward a predetermined disposing position on the corresponding die to pass through, so that the component is able to be aligned and placed at the predetermined disposing position.

The present disclosure also provides a method of using an alignment device, and the method comprises: providing a wafer including a plurality of unsingulated dies; orienting the alignment device described above toward the wafer, thereby allowing the beam passing through the activated liquid crystal switch unit to reach the predetermined disposing position designated for the component; and placing the component at the predetermined disposing position reached by the beam passing through the liquid crystal switch unit.

In the aforementioned alignment device and method, wherein the alignment device further includes a control circuit signally connected to the liquid crystal panel, wherein the control circuit activates the liquid crystal switch unit to allow passage of the beam directed toward the predetermined disposing position from the beam expander.

In the aforementioned alignment device and method, wherein the alignment device further includes a control circuit signally connected to the liquid crystal panel, wherein the control circuit deactivates the liquid crystal switch unit to block the beam that is not directed toward the predetermined disposing position.

In the aforementioned alignment device and method, wherein the wafer has a plurality of the predetermined disposing positions, each of the plurality of predetermined disposing positions corresponds to a respective one of the plurality of components.

In the aforementioned alignment device and method, wherein the plurality of components are first disposed on a carrier and subsequently placed on the wafer by means of the carrier.

The aforementioned method further comprises: performing a dispensing process, wherein an adhesive is applied to the predetermined disposing position reached by the beam passing through the liquid crystal switch unit; bonding the component to the predetermined disposing position via the adhesive; curing the adhesive; and performing a singulation process, wherein the dies with the components placed thereon are separated from each other.

In the aforementioned method, wherein the wafer has a plurality of the predetermined disposing positions, and each of the plurality of predetermined disposing positions corresponds to a respective one of the plurality of components, wherein the plurality of components are first disposed on a carrier and subsequently bonded to the plurality of predetermined disposing positions via the adhesive by means of the carrier.

In the aforementioned method, wherein the carrier is made of a material cured by ultraviolet light, and the adhesive is made of a thermosetting material, wherein after the plurality of components are bonded to the predetermined disposing positions via the adhesive by means of the carrier, the carrier is first cured using ultraviolet light, then the carrier is removed, followed by thermal curing of the adhesive.

It can be seen from above that the present disclosure utilizes a beam expander to enlarge the beam emitted by the laser source. Then, a plurality of liquid crystal switch units of a liquid crystal panel control the passage of multiple accurately aligned beams, directing them simultaneously toward the predetermined disposing positions on the wafer. This enables the simultaneous alignment and disposition of the plurality of components. Therefore, the operational efficiency of the alignment device can be greatly improved, and the production capacity can be effectively increased.

### BRIEF DESCRIPTION OF THE DRAWINGS

FIG. 1A is a schematic view of an embodiment of an alignment device of the present disclosure.

FIG. 1B is a schematic top view of a wafer in the embodiment of the alignment device of the present disclosure.

FIG. 1C is a schematic top view of a liquid crystal panel in the embodiment of the alignment device of the present disclosure.

FIG. 2A to FIG. 2H are schematic views illustrating an embodiment of a method of using the alignment device of the present disclosure.

FIG. 3A and FIG. 3B are schematic views illustrating another embodiment of the method of using the alignment device of the present disclosure.

### DETAILED DESCRIPTION

Implementations of the present disclosure are illustrated using the following embodiments. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships, or adjustments of the sizes, are to be construed as falling within the range covered by the technical content disclosed herein to the extent of not causing changes in the technical effects created and the objectives achieved by the present disclosure. Meanwhile, terms such as “above,” “on,” “below,” “beneath,” “first,” “second,” “a,” “one,” and the like are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

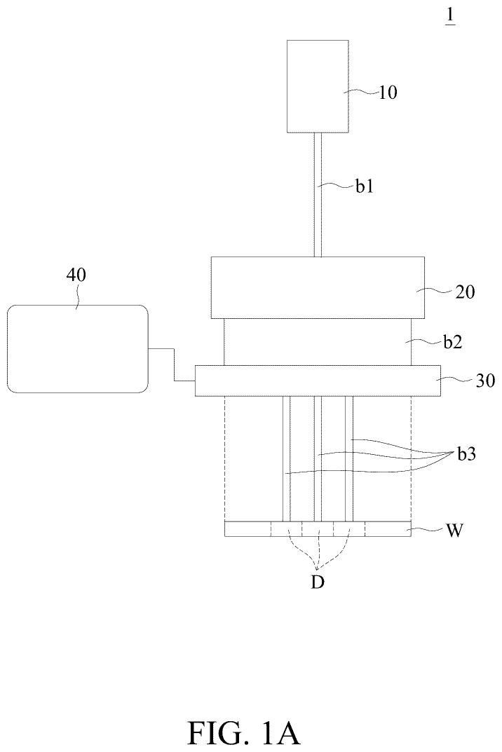

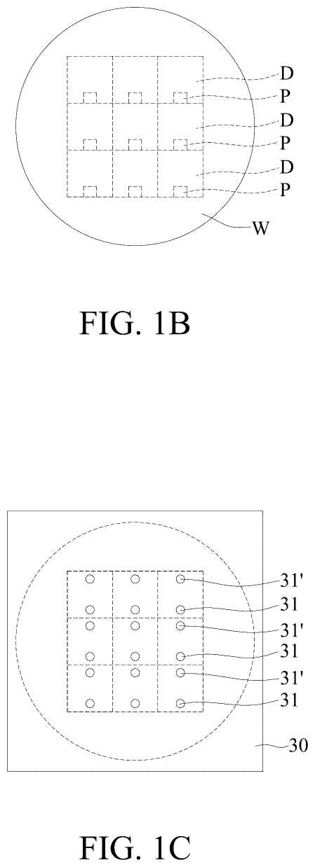

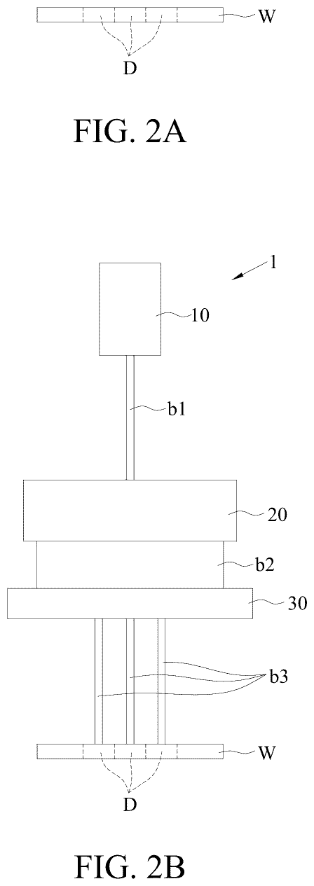

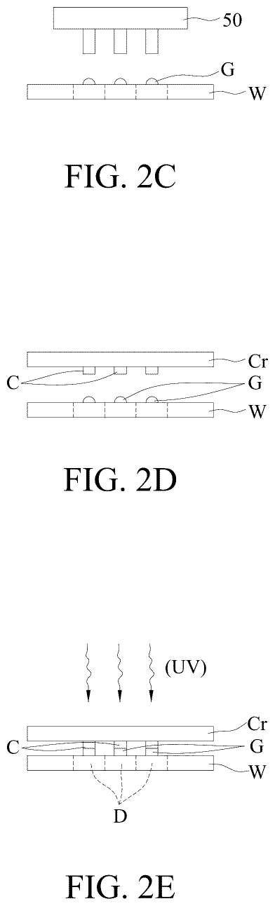

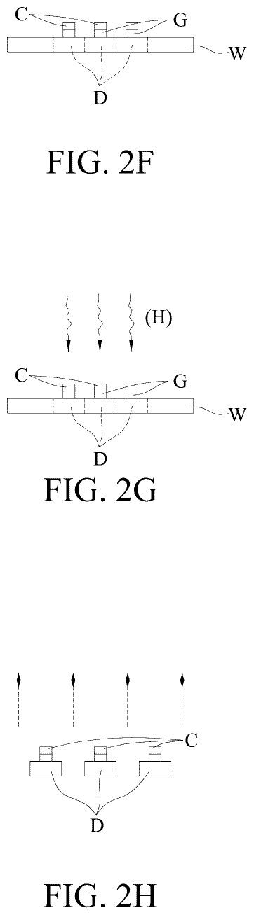

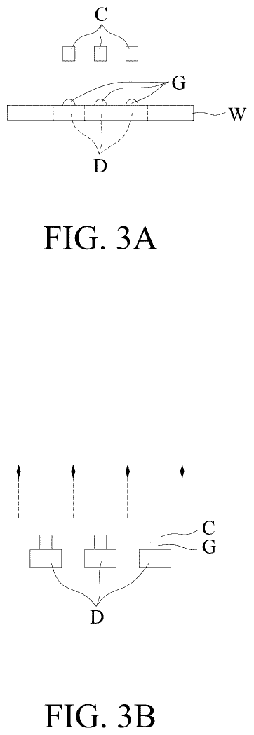

FIG. 1A is a schematic view of an embodiment of an alignment device of the present disclosure. FIG. 1B is a schematic top view of a wafer in the embodiment of the alignment device of the present disclosure. FIG. 1C is a schematic top view of a liquid crystal panel in the embodiment of the alignment device of the present disclosure. FIG. 2A to FIG. 2H are schematic views illustrating an embodiment of a method of using the alignment device of the present disclosure. FIG. 3A and FIG. 3B are schematic views illustrating another embodiment of the method of using the alignment device of the present disclosure.

As shown in FIG. 1A to FIG. 1C, the present embodiment provides an alignment device 1 for aligning a plurality of components C (see also FIG. 2D to FIG. 2H) to a wafer W containing a plurality of unsingulated/undiced dies D. For example, each of the dies D may be an optical engine die (OE die), and each of the components C may be an optical fiber connector, though the examples mentioned here are not limiting.

As shown in FIG. 1A, the alignment device 1 comprises a laser source 10 (a laser light source), a beam expander 20, and a liquid crystal panel 30.

The laser source 10 is used to generate a laser beam b1. The laser beam b1 is emitted toward the beam expander 20 and the wafer W. In general, the laser source 10 used in this embodiment provides a laser beam b1 in the visible light spectrum. However, ultraviolet light UV or other non-visible wavelength laser beams b1 may also be used, and this embodiment does not impose any specific limitations in this regard.

The beam expander 20 is disposed between the laser source 10 and the wafer W to receive the laser beam b1 emitted from the laser source 10. The beam expander 20 then expands the beam's range (diameter) and emits the expanded beam b2 toward the wafer W. The predetermined irradiation area of the expanded beam b2 can cover the plurality of dies D on the wafer W, as shown in FIG. 1B. Preferably, the diameter of the expanded beam b2 formed from the beam expanded by the beam expander 20 is greater than or equal to the diameter of the wafer W, such that all the dies D on the wafer W can be within the coverage area of the expanded beam b2. However, this embodiment does not impose any specific limitations in this regard.

The liquid crystal panel 30 is disposed between the beam expander 20 and the wafer W and has a plurality of liquid crystal switch units 31. Each of the plurality of liquid crystal switch units 31 can be individually controlled by electrical signals to toggle between activation and deactivation. When a liquid crystal switch unit 31 is activated, it allows light to pass through; when it is deactivated, it blocks the light. In general, each of the dies D contained in the wafer W corresponds to at least one liquid crystal switch unit 31. By activating a specific liquid crystal switch unit 31, the corresponding portion of the expanded beam b2 from the beam expander 20 passes through, forming an alignment beam b3 with a cross-section matching the shape of the liquid crystal switch unit 31. The alignment beam b3 is directed toward a predetermined disposing position P on the corresponding die D. In other words, the area illuminated by the alignment beam b3 is the predetermined disposing position P for the component C. This ensures that whether the process is handled manually by operators or automated by equipment, the plurality of components C can be correctly placed at their respective predetermined disposing positions P based on the illuminated areas.

In a preferred aspect of the embodiment, the alignment device 1 further includes a control circuit 40. The control circuit 40 is signally connected to the liquid crystal panel 30 and is used to control the activation of each of the liquid crystal switch units 31 on the liquid crystal panel 30. This allows the corresponding portions of the expanded beam b2 from the beam expander 20, which are directed toward the predetermined disposing positions P, to pass through the liquid crystal switch units 31 and form the alignment beams b3.

In some variant aspects of the embodiment, the control circuit 40 not only controls the activation of each of the liquid crystal switch units 31 but can also control other liquid crystal switch units 31′ to remain deactivated, thereby blocking beams that are not directed toward the predetermined disposing positions P. With this design, the liquid crystal panel 30 becomes a universal type that can accommodate wafer W containing dies D of various designs. Before use, operators only need to select the corresponding liquid crystal switch units, such as the liquid crystal switch units 31 in this embodiment, that match the predetermined disposing positions P on different dies D, and configure the control circuit 40 to activate the corresponding liquid crystal switch units. As for the liquid crystal switch units that do not correspond to the predetermined disposing positions P on the dies D, such as the liquid crystal switch units 31′ in this embodiment, the control circuit 40 can be set to keep the liquid crystal switch units 31′ deactivated. In this way, the liquid crystal panel 30 can correspond to and be applied to the wafer W with the dies D having predetermined disposing positions P for various components C.

Moreover, since the wafer W typically contains multiple dies D that require the installation of the components C, such as optical engine dies D that need optical fiber connectors, the wafer W generally has multiple predetermined disposing positions P, each corresponding to a specific component C. In more advanced manufacturing processes, some of the optical engine dies D or even all of the optical engine dies D may need to mount a plurality of optical fiber connectors, and this embodiment does not impose any specific limitations in this regard.

Furthermore, to further improve manufacturing efficiency, the plurality of components C to be mounted can first be disposed on the bottom surface of a carrier Cr (see also FIG. 2D and FIG. 2E). Using the alignment device 1, all the components C on the bottom surface of the carrier Cr can be simultaneously aligned. Once the alignment is completed, the carrier Cr can be used to place the plurality of components C onto the wafer W at the same time.

Please refer to FIG. 2A to FIG. 2H. This embodiment also provides a method of using the alignment device 1, and the method comprises: providing a wafer W containing a plurality of unsingulated dies D; orienting the alignment device 1 toward the wafer W, allowing the beam passing through the activated liquid crystal switch unit 31 to reach the predetermined disposing position P designated for the component C; and disposing the component C at the predetermined disposing position P reached by the beam passing through the liquid crystal switch unit 31.

More specifically, in the method provided in this embodiment, as shown in FIG. 2A, the first step is to provide a wafer W. The surface of the wafer W has a plurality of dies D arranged or formed, which have not yet been singulated or diced. As mentioned above, each of the dies D has a predetermined disposing position P designated for the component C.

Next, as shown in FIG. 2B, the alignment device 1 is oriented toward the wafer W. Specifically, each of the alignment beams b3, after passing through an activated liquid crystal switch unit 31, is directed toward and irradiates a predetermined disposing position P of a die D on the wafer W, designated for the component C.

Please also refer to FIG. 1A. In a preferred aspect of the embodiment, the alignment device 1 further includes a control circuit 40 signally connected to the liquid crystal panel 30. The control circuit 40 controls and activates the individual liquid crystal switch units 31, allowing alignment beams directed toward the predetermined disposing positions P to pass through. As for the liquid crystal switch units 31′ that correspond to beams not directed toward the predetermined disposing positions P, the control circuit 40 can control and deactivate the liquid crystal switch units 31′ to block the beams.

As shown in FIG. 2C, the next step is the dispensing process. In this step, a dispensing device 50 applies an adhesive G, such as one made of thermosetting/thermocuring material, onto the predetermined disposing positions P reached by the plurality of alignment beams that have passed through the activated liquid crystal switch units 31. This prepares the predetermined disposing positions P for the subsequent attachment of the components C.

Since the wafer W contains multiple dies D, and each die D has at least one predetermined disposing position P for a component C, there are multiple predetermined disposing positions P on the wafer W, each corresponding to a component C. To improve disposition efficiency, the plurality of components C can first be disposed on the bottom surface of a carrier Cr. As shown in FIG. 2D, the carrier Cr, for example, may be made of a transparent material cured by ultraviolet light. Additionally, the carrier Cr can be manufactured to match the shape and size of the wafer W, including alignment features such as flat edges, notches, or other types of alignment markers (not shown) identical to those on the wafer W. This allows operators or automated equipment to first align the carrier Cr with the wafer W. Then, the carrier Cr, along with the components C on its bottom surface, is attached to the surface of the wafer W. The previously applied adhesive G on the wafer W ensures that each component C is attached to its corresponding predetermined disposing position P (see also FIG. 1B). In some variant aspects of the embodiment, each component C may also have a release film or adhesive tape (not shown) attached for protection. This release film or adhesive tape allows the components C to be connected to the bottom surface of the carrier Cr. However, this embodiment does not impose specific limitations in this regard.

Next, as shown in FIG. 2E, ultraviolet light UV is used to irradiate the carrier Cr to cure the carrier Cr. Once the UV curing process is completed, the carrier Cr is then removed, as shown in FIG. 2F, leaving only the components C attached to the surface of the wafer W via the corresponding adhesive G. If the components C were previously attached using a release film or adhesive tape, as described above, the release film or adhesive tape can be removed along with the carrier Cr after the curing process of the carrier Cr is completed.

Then, as shown in FIG. 2G, heat H is applied to the surface of the wafer W to cure the adhesive G, which is made of a thermosetting material. Once the adhesive G has cured, the components C are correctly and firmly placed at their respective predetermined disposing positions P of the dies D of the wafer W.

As shown in FIG. 2H, the next step is the singulation process. In this step, the plurality of dies D on the wafer W, each correctly installed with component C, are cut or diced from the wafer W and separated from one another, resulting in multiple individual dies D with properly positioned components C.

As shown in FIG. 3A, in a variant embodiment, after completing the dispensing process (see FIG. 2C), a plurality of individual components C can be directly aligned to the adhesive G on the wafer W, rather than first disposing the plurality of components C on the carrier Cr as shown in FIG. 2D. Next, the components C are directly bonded to their corresponding predetermined disposing positions P (see also FIG. 1B) via the adhesive G, and then the adhesive G is heated to be cured. The difference from the previous embodiment is that the carrier Cr is omitted in this embodiment. Finally, as shown in FIG. 3B, the singulation process is performed, resulting in a plurality of dies D with the correctly disposed components C.

In summary, the present disclosure utilizes a beam expander to enlarge the beam emitted by the laser source. Then, a plurality of liquid crystal switch units of a liquid crystal panel control the passage of multiple accurately aligned beams, directing them simultaneously toward the predetermined disposing positions on the wafer. This enables the simultaneous alignment and disposition of the plurality of components. Therefore, the operational efficiency of the alignment device can be greatly improved, and the production capacity can be effectively increased.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An alignment device for aligning a plurality of components to a wafer including a plurality of unsingulated dies, the alignment device comprising:
a laser source configured to emit a beam;
a beam expander disposed between the laser source and the wafer, the beam expander configured to receive the beam emitted by the laser source, expand a range of the beam, and direct the beam toward the wafer; and
a liquid crystal panel disposed between the beam expander and the wafer and having a plurality of liquid crystal switch units, wherein each of the plurality of dies corresponds to at least one of the plurality of liquid crystal switch units, wherein activation of the liquid crystal switch unit allows the beam directed toward a predetermined disposing position on the corresponding die to pass through, so that the component is able to be aligned and placed at the predetermined disposing position.

2. The alignment device of claim 1, wherein the alignment device further includes a control circuit signally connected to the liquid crystal panel, wherein the control circuit activates the liquid crystal switch unit to allow passage of the beam directed toward the predetermined disposing position from the beam expander.

3. The alignment device of claim 1, wherein the alignment device further includes a control circuit signally connected to the liquid crystal panel, wherein the control circuit deactivates the liquid crystal switch unit to block the beam that is not directed toward the predetermined disposing position.

4. The alignment device of claim 1, wherein the wafer has a plurality of the predetermined disposing positions, each of the plurality of predetermined disposing positions corresponds to a respective one of the plurality of components.

5. The alignment device of claim 1, wherein the plurality of components are first disposed on a carrier and subsequently placed on the wafer by means of the carrier.

6. A method of using an alignment device, comprising:
providing a wafer including a plurality of unsingulated dies;
orienting the alignment device of claim 1 toward the wafer, thereby allowing the beam passing through the activated liquid crystal switch unit to reach the predetermined disposing position designated for the component; and
placing the component at the predetermined disposing position reached by the beam passing through the liquid crystal switch unit.

7. The method of claim 6, wherein the alignment device further includes a control circuit signally connected to the liquid crystal panel, wherein the control circuit activates the liquid crystal switch unit to allow passage of the beam directed toward the predetermined disposing position from the beam expander.

8. The method of claim 6, wherein the alignment device further includes a control circuit signally connected to the liquid crystal panel, wherein the control circuit deactivates the liquid crystal switch unit to block the beam that is not directed toward the predetermined disposing position.

9. The method of claim 6, wherein the wafer has a plurality of the predetermined disposing positions, each of the plurality of predetermined disposing positions corresponds to a respective one of the plurality of components.

10. The method of claim 6, wherein the plurality of components are first disposed on a carrier and subsequently placed on the wafer by means of the carrier.

11. The method of claim 6, further comprising:
performing a dispensing process, wherein an adhesive is applied to the predetermined disposing position reached by the beam passing through the liquid crystal switch unit;
bonding the component to the predetermined disposing position via the adhesive;
curing the adhesive; and
performing a singulation process, wherein the dies with the components placed thereon are separated from each other.

12. The method of claim 11, wherein the wafer has a plurality of the predetermined disposing positions, and each of the plurality of predetermined disposing positions corresponds to a respective one of the plurality of components, wherein the plurality of components are first disposed on a carrier and subsequently bonded to the plurality of predetermined disposing positions via the adhesive by means of the carrier.

13. The method of claim 12, wherein the carrier is made of a material cured by ultraviolet light, and the adhesive is made of a thermosetting material, wherein after the plurality of components are bonded to the predetermined disposing positions via the adhesive by means of the carrier, the carrier is first cured using ultraviolet light, then the carrier is removed, followed by thermal curing of the adhesive.
